(19) United States
(12) Patent Application Publication
(10) Pub. No.: US 2025/0318079 A1
(43) Pub. Date: Oct. 9, 2025

(54) LIQUID-COOLED ELECTRONIC CONTROL SYSTEM FOR A VEHICLE

(71) Applicant: CONNAUGHT ELECTRONICS Ltd., Tuam (IE)

(72) Inventor: Ramon Casagrande, Tuam (IE)

(73) Assignee: CONNAUGHT ELECTRONICS Ltd., Tuam (IE)

(21) Appl. No.: 18/865,412

(22) PCT Filed: May 11, 2023
(86) PCT No.: PCT/EP2023/062535

§ 371 Date: Nov. 13, 2024

(30) Foreign Application Priority Data
May 13, 2022 (DE) 10 2022 112 001.5

(51) Int. Cl. H05K 7/20

(52) U.S. Cl. CPC H05K 7/20281; H05K 7/20272; H05K 7/20872

(57) ABSTRACT

An electronic control system for a vehicle includes a first and a second electronic control unit (ECU) including a first and a second circuit carrier, respectively, as well as a first and a second cooling channel, respectively. The cooling channels each include respective coolant inlets and coolant outlets. A hydraulic manifold of the electronic control system includes a main inlet, a main outlet, a first and a second ECU outlet as well as a first and a second ECU inlet, to distribute the coolant from the main inlet to the first and the second ECU and from the first and the second ECU to the main outlet.

The present invention is directed to an electronic control system for a vehicle, the control system containing a first electronic control unit, ECU, which comprises at least one first circuit carrier and a first cooling channel for a liquid coolant, wherein the first cooling channel is arranged to cool the at least one first circuit carrier. The invention is further directed to an electronic vehicle guidance system comprising such electronic control system and to a vehicle comprising such electronic vehicle guidance system.

With increasing functionality and computing power of electronic control systems for vehicles, for example for semi-autonomous or fully autonomous driving functions or driver assistance systems, the heat dissipation of electronic components is increasing. It is therefore known to use liquid cooling for those electronic components. However, the liquid cooling commonly is accompanied with an increased assembly space.

It is an objective of the present invention to provide an improved concept for a liquid-cooled electronic control system for a vehicle, which requires less assembly space.

This objective is achieved by the subject-matter of the independent claim. Further implementations and preferred embodiments are subject-matter of the dependent claim.

The invention is based on the idea to provide at least two electronic control units, ECUs, each of them having at least one circuit carrier which is cooled by means of a respective cooling channel for a liquid coolant. In addition, a hydraulic manifold is provided, which is connected to the ECUs, such as to realize a centralized supply of both ECUs with the liquid coolant between a main inlet of the hydraulic manifold and a main outlet of the hydraulic manifold.

According to an aspect of the invention, an electronic control system for a vehicle, in particular a motor vehicle, is provided. The control system contains a first electronic control unit, ECU, which comprises at least one first circuit carrier. The first ECU comprises a first cooling channel for a liquid coolant, such as water or a water based coolant, wherein the first cooling channel is arranged to cool the at least one first circuit carrier. The control system further contains a second ECU, which comprises at least one second circuit carrier and a second cooling channel for the liquid coolant, wherein the second cooling channel is arranged to cool the at least one second circuit carrier. The first cooling channel comprises a coolant inlet for the liquid coolant and a coolant outlet for the liquid coolant, and the second cooling channel also comprises a corresponding coolant inlet for the liquid coolant and a coolant outlet for the liquid coolant. The control system comprises a hydraulic manifold, which comprises a main inlet for the liquid coolant and a main outlet for the liquid coolant. The hydraulic manifold comprises a first ECU outlet, which is connected to the coolant inlet of the first ECU to distribute the coolant from the main inlet to the first ECU. The hydraulic manifold comprises a second ECU outlet, which is connected to the coolant inlet of the second ECU to distribute the coolant from the main inlet to the second ECU. The hydraulic manifold comprises a first ECU inlet, which is connected to the coolant outlet of the first ECU to distribute the coolant from the first ECU to the main outlet. The hydraulic manifold comprises a second ECU inlet, which is connected to the coolant outlet of the second ECU to distribute the coolant from the second ECU to the main outlet.

A circuit carrier may also be denoted as circuit board and may in some implementations be implemented as a printed circuit board, PCB.

A cooling channel may for example be understood as a hollow space within the respective ECU and extends between the respective coolant inlet and the respective coolant outlet. The cooling channel may be formed by one or more components of the respective ECU, wherein this one or more component defines a boundary of the respective cooling channel. For example, the respective cooling channel is arranged with respect to the at least one circuit carrier of the respective ECU such that in case the coolant is present within the cooling channel, in particular is flowing through the cooling channel, it may take up heat, which is dissipated by one or more electronic components of the at least one respective circuit carrier.

The first and second ECU outlet as well as the first and second ECU inlet of the hydraulic manifold may be connected to the coolant inlets and coolant outlets, respectively, of the corresponding ECUs by means of one or more hoses, pipes, tubes or other connections for guiding the liquid coolant.

The main inlet of the hydraulic manifold may for example be connected to a source for providing the liquid coolant wherein the source is arranged separately to the electronic control system in the vehicle. Furthermore, the main outlet of the hydraulic manifold may for example be connected to a corresponding drain for the liquid coolant, wherein the drain is also arranged externally to the electronic control system in the vehicle. The vehicle may, for example, comprise means for recirculating or conditioning or re-cooling of the liquid coolant received by the drain from the main outlet and provided again via the source to the main inlet. To this end, the vehicle may also comprise a transportation system for the liquid coolant including, for example, one or more pumps to convey the liquid coolant from the source to the main inlet through the cooling channels back to the main outlet and the drain and so forth.

In particular, if all ECU inlets and all ECU outlets of the hydraulic manifold are connected accordingly to the respective ECUs, the main inlet and the main outlet may thus be the only two connections of the electronic control system for supplying the liquid coolant to the electronic control system and draining the liquid coolant from the electronic control system, respectively.

Consequently, the supply of the electronic control system with the liquid coolant may be implemented in a particularly compact way by providing the hydraulic manifold according to the invention. This eventually leads to a decreased assembly space of the electronic control system, in particular compared to an alternative arrangement, where the first and the second ECUs are supplied with the liquid coolant separately and individually.

The flow of the liquid coolant may for example be given in two branches, for example parallel branches. The first branch may extend from the main inlet via the first ECU outlet, the coolant inlet of the first ECU, the coolant outlet of the first ECU to the first ECU inlet of the hydraulic manifold and to the main outlet. The second branch may extend from the main inlet via the second ECU outlet, the coolant inlet of the second ECU, the coolant outlet of the second ECU, the second ECU inlet of the hydraulic manifold and the main outlet.

According to several implementations of the electronic control system, the first ECU comprises a first housing, wherein the at least one first circuit carrier is arranged within the first housing and the first cooling channel is at least partially arranged within the first housing.

According to several implementations, the second ECU comprises a second housing, wherein the at least one second circuit carrier is arranged within the second housing and the second cooling channel is arranged at least in part within the second housing.

According to several implementations, the first housing and the second housing are stacked onto each other.

In particular, a form factor or outer dimensions of the first housing is identical or approximately identical to a form factor or outer dimensions of the second housing. For example, the first and the second housing may be approximately of cuboid shape meaning that the first ECU and the second ECU would fit into respective virtual cuboids. Stacking the first and the second housing on top of each other or onto each other may be understood such that the respective faces of the cuboid shape face each other.

In other words, stacking the first and the second housing onto each other may be understood such that from a viewing direction along a stacking direction, the first housing occludes the second housing essentially completely or vice versa.

In this way, the total arrangement of the first and the second ECU requires less space and consequently, the total assembly space of the electronic control system is reduced further.

According to several implementations, the first ECU comprises at least two first support elements attached at an exterior of the first housing, wherein each of the at least two first support elements extends along a stacking direction of the first housing stacked to the second housing. The second ECU comprises at least two second support elements attached at an exterior of the second housing and extending along the stacking direction. Each of the at least two first support elements is fastened to a corresponding one of the at least two second support elements.

In other words, the first housing and the second housing are connected or fastened to each other by means of the first and the second support elements. The support elements can, for example, be designed as elongated pillar-like or cylinder-like or prism-like, for example rectangular prism-like, elements, which define a desired position and distance of the ECUs and the first and the second housing with respect to each other when fastened to each other. Consequently, the first and the second ECU are rigidly connected to each other by means of the first and second support elements without the need for a rack holder for receiving the first and the second housing, respectively.

Consequently, a main housing of the electronic control system may be designed simpler because it does not require means for positioning the first and the second ECU with respect to each other, or the main housing may be omitted altogether.

According to several implementations, each of the at least two first support elements is fastened to the corresponding one of the at least two second support elements by at least one respective screw, threaded rod or bolt, which extends through the respective first and second support element along the stacking direction.

In this way, a reliable and robust connection of the ECUs with respect to each other is achievable, and, since the screw, threaded rod or bolt extends through the support elements, no additional assembly space is required for other connection means.

According to several implementations, the electronic control system comprises a main housing. The first ECU and the second ECU, in particular the first housing and the second housing, are fastened within the main housing at respective receptacles.

In other words, the main housing comprises, in an interior, one or more receptacles for the first ECU and one or more receptacles for the second ECU, which may be used to fasten the first and the second housing, respectively, to the main housing. The receptacles may, for example, be designed as slits, slide-in features or the like, such that the first housing and the second housing may be inserted or slid in the main housing at the respective receptacles. In this way, the design of the first and the second housing of the first and the second ECU, respectively, may be simplified.

According to several implementations, the at least one first circuit carrier comprises two first circuit carriers, which are arranged on opposite sides of the first cooling channel. Alternatively or in addition, the at least one second circuit carrier comprises two second circuit carriers, which arranged on opposite sides of the second cooling channel.

In other words, the first cooling channel is arranged to cool two first circuit carriers at the same time and/or the second cooling channel is arranged to cool two second circuit carriers at the same time. In this way, the efficiency of the cooling by the liquid coolant may be optimized. In particular, the use of one cooling channel for cooling at least two circuit carriers further reduces the total assembly space of the electronic control system.

According to several implementations, the electronic control system comprises at least one connector component, which connects the at least one first circuit carrier electrically to the at least one second circuit carrier.

In this way, the first ECU and the second ECU may communicate based on a wired communication with each other and/or the first ECU may supply the second ECU with electrical energy or vice versa. Also this contributes to a reduced assembly space of the total electronic control system.

According to several implementations, the hydraulic manifold comprises a solid body, an inlet chamber for the coolant within the solid body and an outlet chamber for the coolant within the solid body. The main inlet, the first ECU outlet and the second ECU outlet are connected to the inlet chamber. The main outlet, the first ECU inlet and the second ECU inlet are connected to the outlet chamber.

The inlet chamber and the outlet chamber are disconnected from each other or, in other words, are separated from each other such that the liquid coolant cannot directly enter the inlet chamber from the outlet chamber or vice versa.

According to several implementations, the hydraulic manifold comprises tuning means, which are arranged and configured to tune a flow rate of the liquid coolant from the main inlet to the first ECU outlet and/or from the main inlet to the second ECU outlet and/or from the first ECU inlet to the main outlet and/or from the second ECU inlet to the main outlet. In other words, the hydraulic manifold is designed as a tunable hydraulic manifold.

The tuning means may, for example, comprise one or more respective tunable valves for tuning the respective flow rate. In this way, the distribution of the liquid coolant amongst the first and the second ECU may be tuned as desired, in particular such that a particular homogeneous coolant flow is achieved and consequently a homogeneous cooling of the first and the second ECU is achieved.

According to a further aspect of the invention, an electronic vehicle guidance system for a vehicle is provided. The electronic vehicle guidance system comprises an electronic control system according to the invention, wherein the first ECU and/or the second ECU is configured to receive sensor data from at least one sensor system of the vehicle and to generate at least one control signal for affecting a lateral and/or longitudinal control of the vehicle and/or to generate at least one further control signal to inform or warn a driver of the vehicle.

An electronic vehicle guidance system may be understood as an electronic system, configured to guide a vehicle in a fully automated or a fully autonomous manner and, in particular, without a manual intervention or control by a driver or user of the vehicle being necessary. The vehicle carries out all required functions, such as steering maneuvers, deceleration maneuvers and/or acceleration maneuvers as well as monitoring and recording the road traffic and corresponding reactions automatically. In particular, the electronic vehicle guidance system may implement a fully automatic or fully autonomous driving mode according to level 5 of the SAE J3016 classification. An electronic vehicle guidance system may also be implemented as an advanced driver assistance system, ADAS, assisting a driver for partially automatic or partially autonomous driving. In particular, the electronic vehicle guidance system may implement a partly automatic or partly autonomous driving mode according to levels 1 to 4 of the SAE J3016 classification. Here and in the following, SAE J3016 refers to the respective standard dated June 2018.

Guiding the vehicle at least in part automatically may therefore comprise guiding the vehicle according to a fully automatic or fully autonomous driving mode according to level 5 of the SAE J3016 classification. Guiding the vehicle at least in part automatically may also comprise guiding the vehicle according to a partly automatic or partly autonomous driving mode according to levels 1 to 4 of the SAE J3016 classification.

According to a further aspect of the invention, a vehicle, in particular a motor vehicle, comprising an electronic control system according to the invention or an electronic vehicle guidance system according to the invention is provided.

In some implementations, the vehicle may comprise the source and/or the drain for the liquid coolant and, for example, the transportation system for supplying the electronic control system with the liquid coolant and for draining the liquid coolant from the electronic control system.

Further features of the invention are apparent from the claims, the figures and the figure description. The features and combinations of features mentioned above in the description as well as the features and combinations of features mentioned below in the description of figures and/or shown in the figures may be comprised by the invention not only in the respective combination stated, but also in other combinations. In particular, embodiments and combinations of features, which do not have all the features of an originally formulated claim, may also be comprised by the invention. Moreover, embodiments and combinations of features which go beyond or deviate from the combinations of features set forth in the recitations of the claims may be comprised by the invention.

In the following, the invention will be explained in detail with reference to specific exemplary implementations and respective schematic drawings. In the drawings, identical or functionally identical elements may be denoted by the same reference signs. The description of identical or functionally identical elements is not necessarily repeated with respect to different figures.

In the figures:

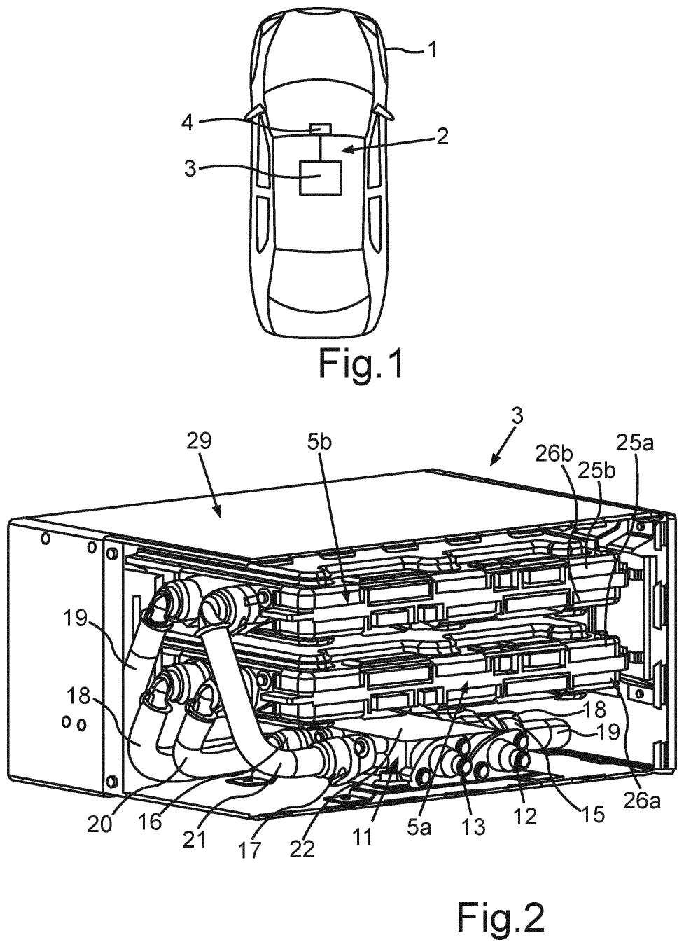

FIG. 1 shows a schematic representation of an exemplary implementation of a vehicle according to the invention;

FIG. 2 shows a schematic representation of an exemplary implementation of an electronic control system according to the invention;

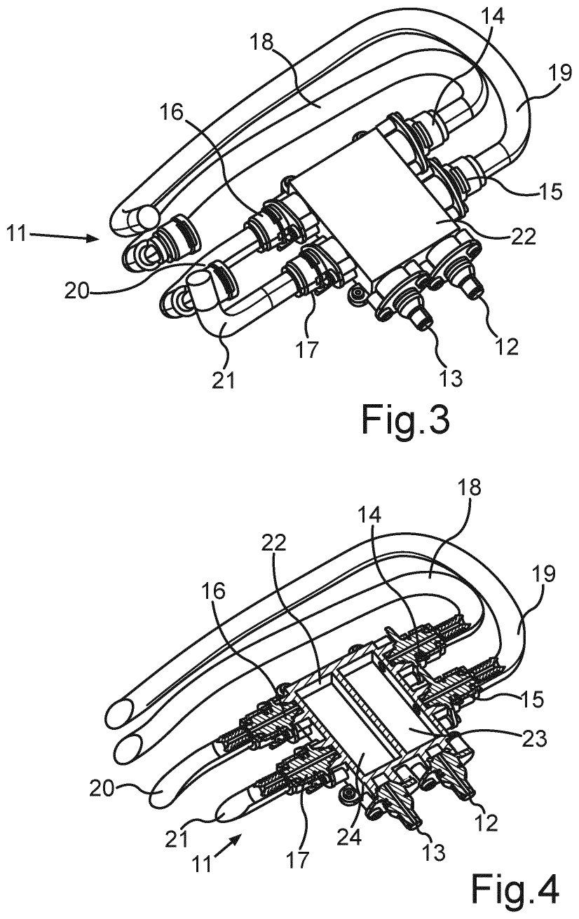

FIG. 3 shows a schematic representation of a hydraulic manifold of a further exemplary implementation of an electronic control system according to the invention;

FIG. 4 shows the hydraulic manifold of FIG. 3 partially cut open for illustrative purposes;

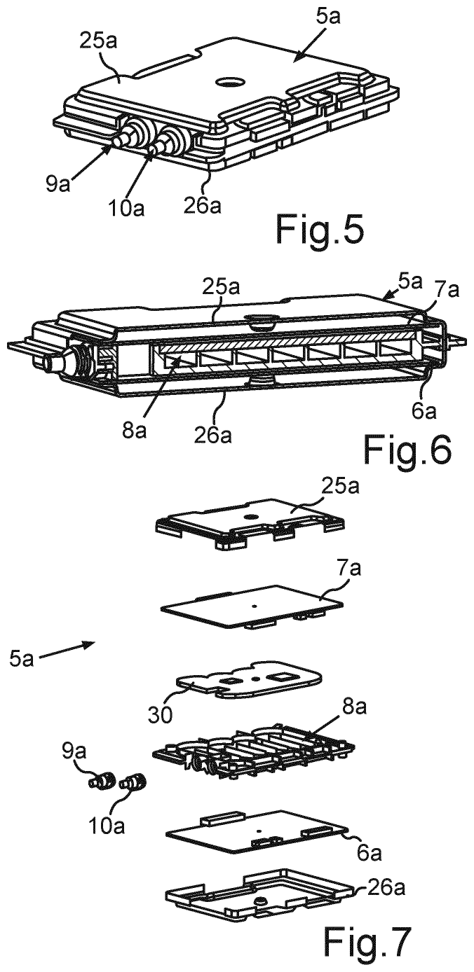

FIG. 5 shows an exemplary implementation of an ECU for use in a further exemplary implementation of an electronic control system according to the invention;

FIG. 6 shows a sectional view of the ECU of FIG. 5;

FIG. 7 shows an explosion view of the ECU of FIG. 5;

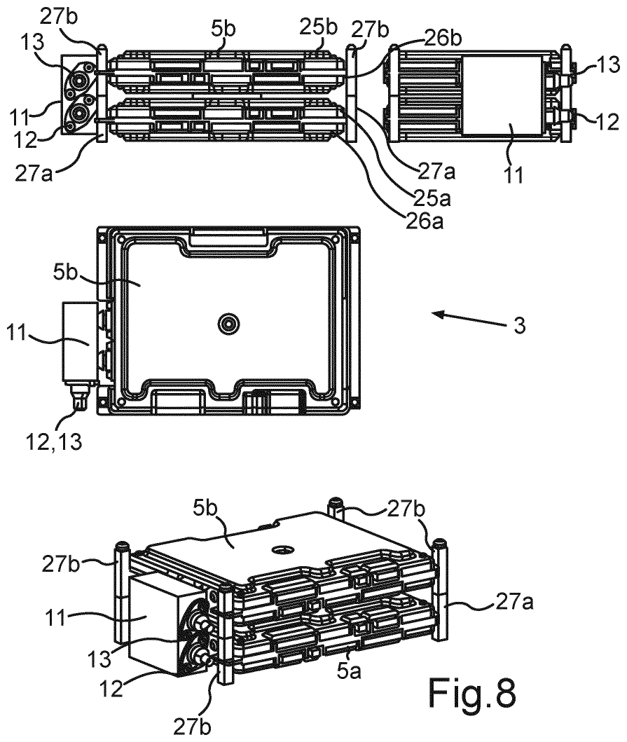

FIG. 8 shows a schematic representation of a further exemplary implementation of an electronic control system according to the invention in various views;

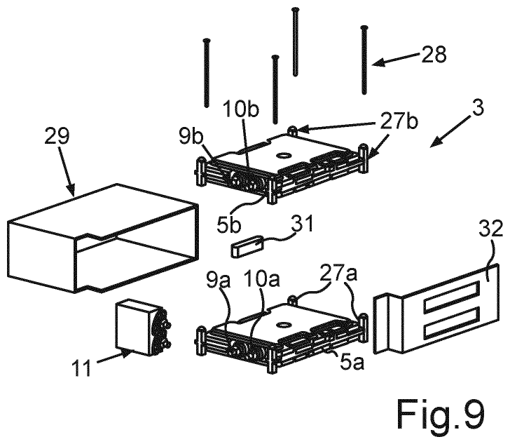

FIG. 9 shows an explosion view of a further exemplary implementation of an electronic control system according to the invention;

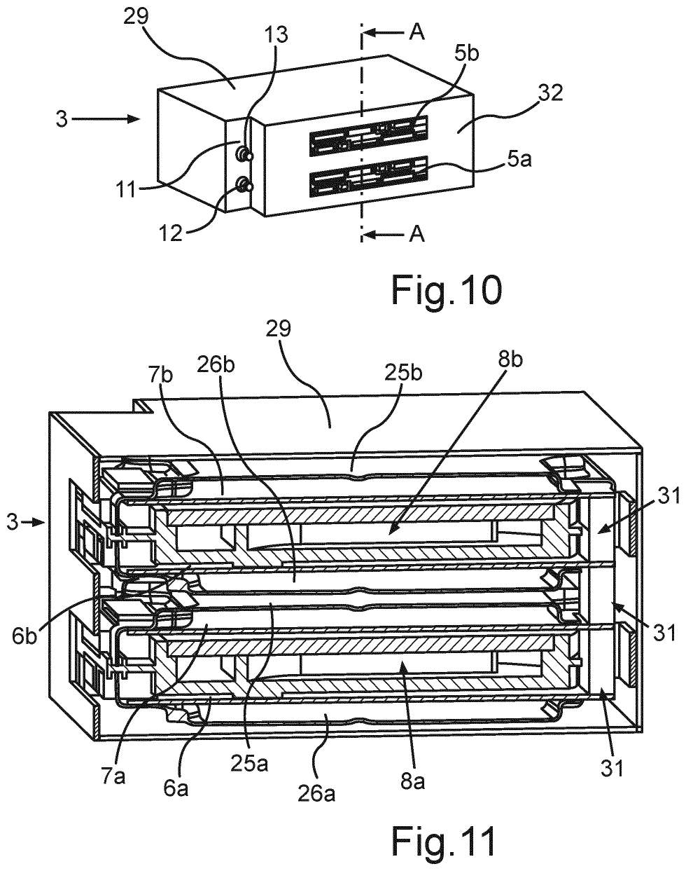

FIG. 10 shows a perspective view of the electronic control system of FIG. 9;

FIG. 11 shows a sectional view of the electronic control system of FIG. 10;

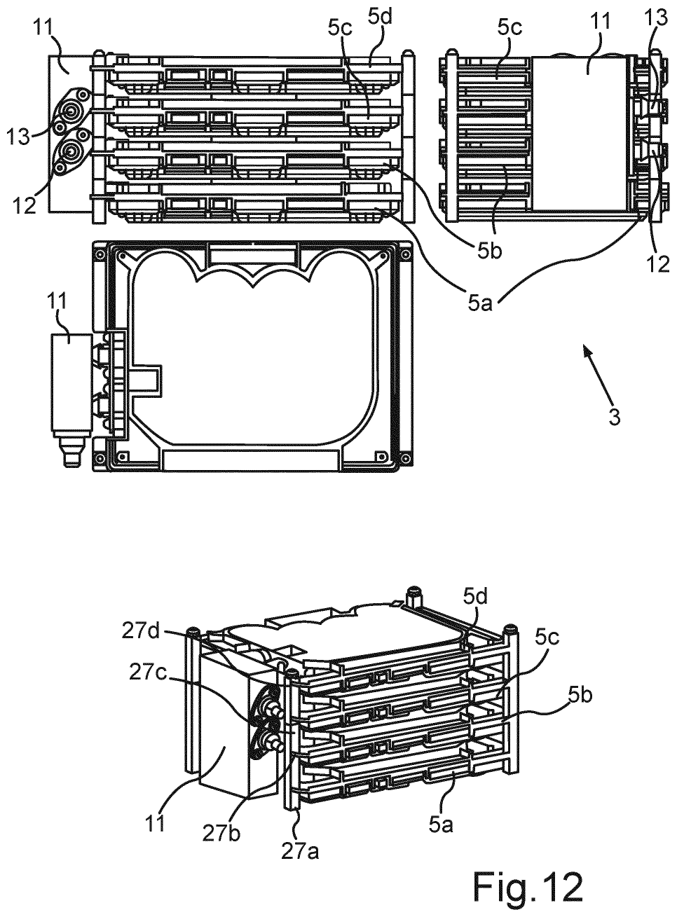

FIG. 12 shows a schematic representation of a further exemplary implementation of an electronic control system according to the invention in various views;

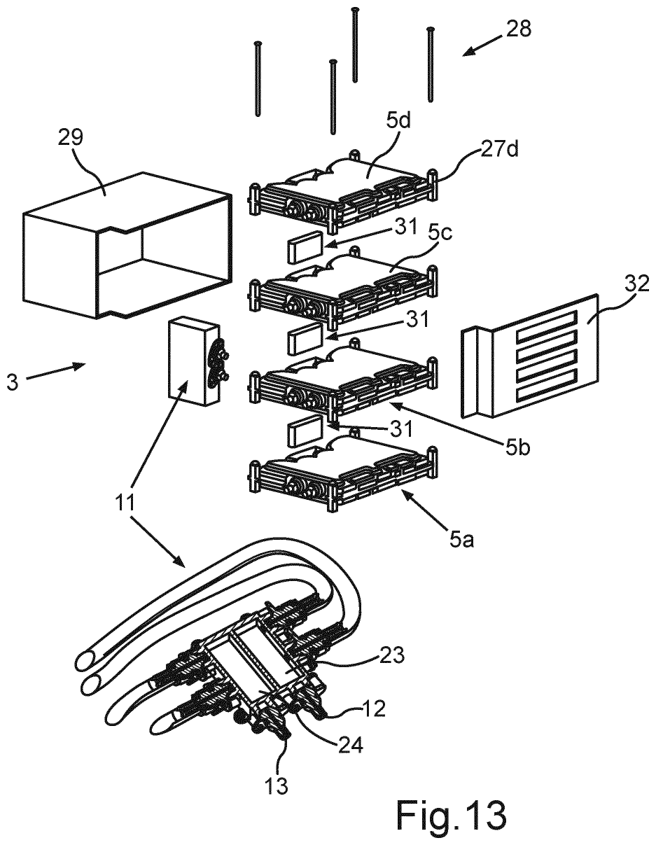

FIG. 13 shows an explosion view of a further exemplary implementation of an electronic control system according to the invention;

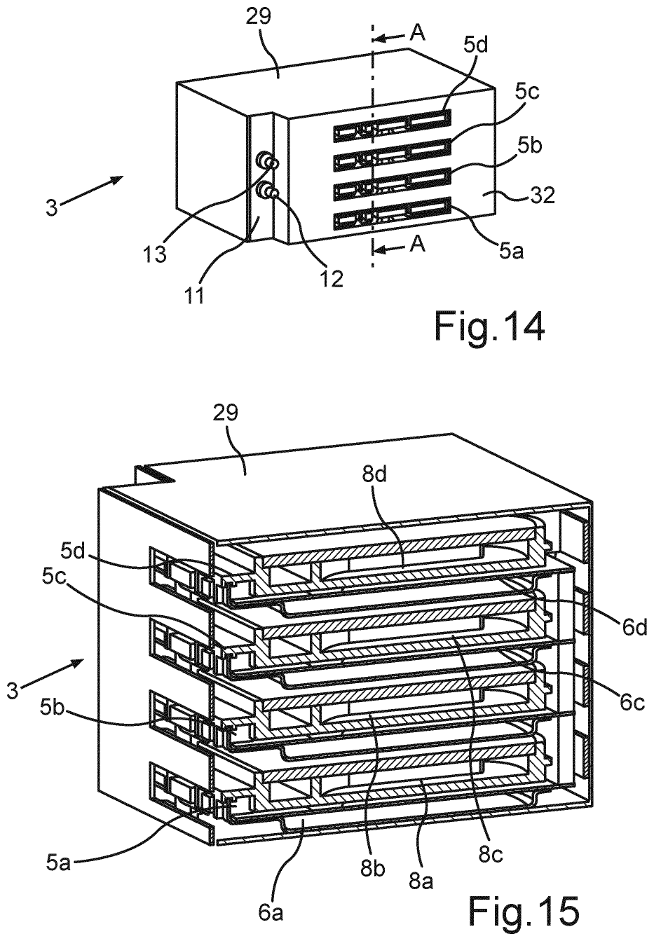

FIG. 14 shows a perspective view of the electronic control system of FIG. 13; and

FIG. 15 shows a sectional view of the electronic control system of FIG. 14.

FIG. 1 shows schematically a top view of a motor vehicle 1 with an electronic vehicle guidance system 2, which comprises an electronic control system 3 according to the invention and, for example, an environmental sensor system 4, for example a camera, a radar system, a lidar system, a rain-light sensor, an ultrasonic sensor system et cetera.

FIG. 2 shows a perspective view of an exemplary implementation of an electronic control system 3 according to the invention, wherein for illustrative purposes parts of a main housing 29 of the electronic control system 3 are not shown.

The control system 3 comprises a first ECU 5a and a second ECU 5b, which are both arranged within the main housing 29 in the shown example. However, in other exemplary implementations, the main housing 29 may also be omitted. An exemplary implementation of the first ECU 5a is shown schematically in a perspective view in FIG. 5, in a sectional view in FIG. 6 and in an explosion view in FIG. 7. The second ECU 5b may, for example, be implemented analogously.

The first ECU 5a comprises a first circuit carrier 6a and a first cooling channel 8a formed by a respective cooling component of the ECU 5a, which is arranged with respect to the first circuit carrier 6a such that heat dissipated by electronic components of the first circuit carrier 6a may be taken by a liquid coolant within the first cooling channel 8a such that the first ECU 5a is cooled.

Optionally, the first ECU 5a may comprise a further first circuit carrier 7a. In this case, the first circuit carriers 6a, 7a are arranged on opposite sides of the cooling channel 8a such that the cooling channel cools both of the first circuit carriers 6a, 7a. Analogously, the second ECU 5b comprises at least one second circuit carrier 6b, 7b (not shown in FIG. 2) and a corresponding second cooling channel 8b (not shown in FIG. 2). Each of the first and the second cooling channel 8a, 8b comprises a respective coolant inlet 9a for the liquid coolant and a respective coolant outlet 10a for the liquid coolant.

Furthermore, the electronic control system 3 comprises a hydraulic manifold 11 as shown in FIG. 2 and separately in a perspective view in FIG. 3 and FIG. 4 partially cut open for illustrative purposes.

The hydraulic manifold 11 comprises a main inlet 12 and a main outlet 13 for the liquid coolant. The main inlet 12 may, for example, be connected to a source of a coolant circuit (not shown) of the vehicle 1 and the main outlet 13 may be connected to a drain of the coolant circuit of the vehicle 1.

The hydraulic manifold 11 comprises a first ECU outlet 14, which is connected to the coolant inlet 9a of the first ECU to distribute the coolant from the main inlet 12 to the first ECU 5a. The hydraulic manifold 11 also comprises a second ECU outlet 15, which is connected to the coolant inlet 9b of the second ECU 5b to distribute the coolant from the main inlet 12 to the second ECU 5b. Furthermore, the hydraulic manifold 11 comprises a first ECU inlet 16, which is connected to the coolant outlet 10a of the first ECU 5a to distribute the coolant from the first ECU 5a to the main outlet 13. The hydraulic manifold 11 also comprises a second ECU inlet 17, which is connected to the coolant outlet 10b of the second ECU 5b to distribute the coolant from the second ECU 5b to the main outlet 13.

For connecting the ECU inlets 16, 17 and the ECU outlets 14, 15 to the respective coolant inlets 9a, 9b and coolant outlets 10a, 10b, respectively, the hydraulic manifold 11 may comprise respective hosing pipes or tubes 18, 19, 20, 21.

As shown exemplarily in FIG. 4, the hydraulic manifold 11 may for example comprise a solid body 22, wherein an inlet chamber 23 and an outlet chamber 24, which is separated from the inlet chamber 23, are arranged in the solid body 22. The main inlet 12, the first ECU outlet 14 and the second ECU outlet 15 are connected to the inlet chamber 23 or are arranged at the inlet chamber 23, in other words. The main outlet 13, the first ECU inlet 16 and the second ECU inlet 17 are connected to the outlet chamber 24 or, in other words, are arranged at the outlet chamber 24.

As shown for example in FIG. 7, the first ECU 5a may comprise two housing components 25a, 26a, which may form a housing of the first ECU 5a when attached to each other. The housing components 25a, 26a may form an enclosure, which accommodates the first ECU 5a and the component or components forming the cooling channel 8a as well as, if applicable, the further first circuit carrier 7a. For example, a cover 30 may be arranged between the first circuit carrier 6a and the cooling channel 8a and, if applicable, between the further first circuit carrier 7a and the cooling channel 8a, in order to increase the thermal conductivity between the first circuit carriers 6a, 7a and the cooling channel 8a or the coolant, respectively.

In the implementation of FIG. 2 to FIG. 7, the ECUs 5a, 5b may, for example, be slid into the main housing 29, which may comprise respective receptacles to take up the ECUs 5a, 5b.

FIG. 10 shows a further exemplary implementation of an electronic control system 3 according to the invention in a perspective view, and FIG. 9 shows the electronic control system 3 of FIG. 10 in an explosion view, while FIG. 11 shows the electronic control system 3 of FIG. 10 in a sectional view along the sectional line AA. The electronic control system 3 of FIG. 10 may, for example, comprise main housing 29. FIG. 8 shows the electronic control system 3 in various views without the main housing 29.

The main housing 29 may accommodate the first and the second ECU 5a, 5b and may, for example, be open on one side such that the ECUs 5a, 5b may be arranged within the main housing 29. Furthermore, the electronic control system 3 may optionally comprise a cover 32, which closes the open side of the main housing 29 partially leaving open access openings for accessing the first and the second ECU 5a, 5b by means of electrical connectors (not shown).

In the implementations of FIG. 8 to FIG. 11, the first ECU 5a may have four supporting elements 27a, for example, one at each corner of the housing of the first ECU 5a. The support elements 27a may, for example, have the shape of elongated cuboids or pillars extending along a stacking direction, which may, for example, be perpendicular to a plane of the circuit carriers 6a, 7a. Analogously, the second ECU 5b has corresponding support elements 27b, for example, one at each edge of the housing of the second ECU 5b. The support elements 27a, 27b may be designed such that they match together when the first ECU 5a and the second ECU 5b are stacked onto each other along the stacking direction.

Each of the support elements 27a of the first ECU 5a may be in contact with a corresponding supporting element 27b of the second ECU 5b. For example, the supporting elements 27a of the first ECU 5a may be fastened to the respective support elements 27b of the second ECU 5b by appropriate fastening means, such as, for example, screws 28. For example, the supporting elements 27a and 27b may be hollow inside such that the screws 28 may extend through the supporting elements 27a and 27b along the stacking direction to fasten the supporting elements 27a, 27b to each other.

Consequently, the first and the second ECU 5a, 5b are rigidly connected together before they are inserted in the main housing 29. Therefore, the main housing 29 may not necessarily comprise receptacles for fastening the ECUs 5a, 5b individually. In fact, the main housing 29 may be omitted, and the first and the second ECU 5a, 5b are still arranged in a defined and fixed position with respect to each other.

As can be seen from FIG. 11, also in this implementation, the ECUs 5a, 5b may each have, for example, two circuit carriers 6a, 7a and 6b, 7b respectively. However, in other implementations, each of the ECUs 5a, 5b may only have one respective circuit carrier 6a, 7b.

The first ECU 5a and the second ECU 5b may, for example, be connected electrically to each other by means of a connection element 31. For example, the connection element 31 may be implemented as a circuit board connector and may connect a first circuit carrier 6a, 7a of the first ECU 5a to a second circuit carrier 6b, 7b of the second ECU 5b. For example, if each of the ECUs 5a, 5b comprises two respective circuit carriers 6a, 7a, 6b, 7b, the two circuit carriers 7a, 6a, which face each other in the stacking arrangement, may be directed to each other by means of the connection element 31. For example, further connection elements 31 may connect the two circuit carriers 6a, 7a of the first ECU 5a to each other and/or the two circuit carriers 6b, 7b of the second ECU 5b to each other.

FIG. 14 shows a further exemplary implementation of an electronic control system 3 according to the invention. The electronic control system 3 may also have the main housing 29 as described and as shown in FIG. 14. FIG. 13 shows an explosion view of the electronic control system 3 according to FIG. 14, and FIG. 15 shows a corresponding sectional view along a sectional line AA of FIG. 14. FIG. 12 shows the electronic control system 3 of FIG. 13 to FIG. 15 in various views without the main housing 29.

In addition to the first and the second ECU 5a, 5b, the electronic control system 3 of FIG. 11 to FIG. 15 comprises a third ECU 5c and a fourth ECU 5d. All four ECUs 5a, 5b, 5c, 5d may, for example, be stacked onto each other along the stacking direction as described with respect to the implementation of FIG. 8 to FIG. 11. In particular, also the third and the fourth ECU 5c, 5d may comprise respective supporting elements 27c and 27d, respectively.

In the example of FIG. 15, the first and the second ECU 5a, 5b comprise the first circuit carrier 6a and the second circuit carrier 6b, respectively, but not the further first circuit carrier 7a and the further second circuit carrier 7b, respectively. Analogously, also the third ECU 5c comprises a third circuit carrier 6c, and the fourth ECU 5d comprises a fourth circuit carrier 6d. Furthermore, the third ECU 5c comprises a third cooling channel 8c, and the fourth ECU 5d comprises a fourth cooling channel 8d. The explanations with respect to the first and the second cooling channel 8a, 8b carry over analogously to the third and the fourth cooling channel 8c, 8d.

Furthermore, each of the third and fourth cooling channel 8c, 8d comprise a respective coolant inlet and a respective coolant outlet (not shown). The hydraulic manifold 11 may comprise a third ECU outlet, a fourth ECU outlet, a third ECU inlet and a fourth ECU inlet (not shown). The third ECU outlet is connected to the coolant inlet of the third ECU, for example, via a respective hose, and the fourth ECU outlet is connected to the coolant inlet of the fourth ECU, for example, by means of a respective hose. In this way, the coolant may be distributed from the main inlet also to the third ECU 5c and the fourth ECU 5d.

Furthermore, the third ECU inlet may be connected to the coolant outlet of the third ECU, and the fourth ECU inlet may be connected to the coolant outlet of the fourth ECU 5d. In this way, the coolant may also be distributed from the third ECU 5c and the fourth ECU 5d to the main outlet 13. As described, in particular with respect to the figures, the invention allows to reduce the total assembly space of a liquid-cooled electronic control system for a vehicle, which has two or more liquid-cooled ECUs.

1. An electronic control system for a vehicle, the electronic control system comprising:
a first electronic control unit, ECU, comprising:
at least one first circuit carrier, and
a first cooling channel for a liquid coolant,
wherein the first cooling channel is arranged to cool the at least one first circuit carrier;
a second ECU comprising:
at least one second circuit carrier; and
a second cooling channel for the liquid coolant,
wherein the second cooling channel is arranged to cool the at least one second circuit carrier,
wherein each of the first cooling channel and the second cooling channel comprises a respective coolant inlet and a respective coolant outlet;
a hydraulic manifold comprising:
a main inlet;
a main outlet;
a first ECU outlet, which is connected to the coolant inlet of the first ECU to distribute the coolant from the main inlet to the first ECU; and
a second ECU outlet, which is connected to the coolant inlet of the second ECU to distribute the coolant from the main inlet to the second ECU;
a first ECU inlet, which is connected to the coolant outlet of the first ECU to distribute the coolant from the first ECU to the main outlet; and
a second ECU inlet, which is connected to the coolant outlet of the second ECU to distribute the coolant from the second ECU (5b) to the main outlet (13)
tuning means arranged and configured to tune a flow rate of the liquid coolant from the main inlet to the first ECU outlet and/or from the main inlet to the second ECU outlet and/or from the first ECU inlet to the main outlet and/or from the second ECU inlet to the main outlet.

2. The electronic control system according to claim 1,
wherein the first ECU comprises a first housing,
wherein the at least one first circuit carrier is arranged within the first housing and the first cooling channel is arranged at least in part within the first housing,
wherein the second ECU comprises a second housing,
wherein the at least one second circuit carrier is arranged within the second housing and the second cooling channel is arranged at least in part within the second housing, and
wherein the first housing and the second housing are stacked onto each other.

3. The electronic control system according to claim 2,
wherein the first ECU comprises at least two first support elements attached at an exterior of the first housing and extending along a stacking direction of the first housing and the second housing,
wherein the second ECU comprises at least two second support elements attached at an exterior of the second housing and extending along the stacking direction, and
wherein each of the at least two first support elements is fastened to a corresponding one of the at least two second support elements.

4. The electronic control system according to claim 3,
wherein each of the at least two first support elements is fastened to the corresponding one of the at least two second support elements by at least one respective screw, threaded rod or bolt, which extends through the respective first and second support element along the stacking direction.

5. The electronic control system according to claim 1, further comprising:
a main housing,
wherein the first ECU and the second ECU are fastened within the main housing at respective receptacles.

6. The electronic control system according to claim 1,
wherein the at least one first circuit carrier comprises two first circuit carriers arranged on opposite sides of the first cooling channel, and/or
wherein the at least one second circuit carrier comprises two second circuit carriers arranged on opposite sides of the second cooling channel.

7. The electronic control system according to claim 1, further comprising:
at least one connector component connecting the at least one first circuit carrier electrically to the at least one second circuit carrier.

8. The electronic control system according to claim 1,
wherein the hydraulic manifold further comprises:
a solid body; and
an inlet chamber within the solid body,
wherein the main inlet, the first ECU outlet and the second ECU outlet are connected to the inlet chamber; and/or
an outlet chamber within the solid body,
wherein the main outlet, the first ECU inlet and the second ECU inlet are connected to the outlet chamber.

9. (canceled)

10. An electronic vehicle guidance system for a vehicle comprising:
an electronic control system according to claim 1,
wherein the first ECU and/or the second ECU is configured to receive sensor data from at least one sensor system of the vehicle and to generate at least one control signal for affecting a lateral and/or longitudinal control of the vehicle and/or to generate at least one further control signal to inform or warn a driver of the vehicle.

11. A vehicle comprising an electronic control system according to claim 1.
